(19) United States
(12) Patent Application Publication
(10) Pub. No.: US 2025/0349630 A1
(43) Pub. Date: Nov. 13, 2025

(54) METHOD FOR MANUFACTURING SEMICONDUCTOR PACKAGE AND SEMICONDUCTOR PACKAGE MANUFACTURED BY USING THE SAME

(71) Applicant: Samsung Electronics Co., Ltd., Suwon-si (KR)

(72) Inventors: Hojin SEO, Suwon-si (KR); Sunwoo HAN, Suwon-si (KR); Insik HAN, Suwon-si (KR)

(21) Appl. No.: 18/981,810

(22) Filed: Dec. 16, 2024

(30) Foreign Application Priority Data
May 9, 2024 (KR) 10-2024-0061383

(51) Int. Cl. H01L 23/04; H01L 21/50; H01L 23/00; H01L 23/367

(52) U.S. Cl. CPC H01L 23/041; H01L 21/50; H01L 23/3675; H01L 23/562

(57) ABSTRACT

A method of manufacturing a semiconductor package having improved warpage resistance and an improved heat dissipation characteristic. The method of manufacturing the semiconductor package includes mounting a first semiconductor chip on a first surface of the package substrate, forming a stiffener on a first surface of a plate, forming a first adhesive layer on the first semiconductor chip, disposing the stiffener and the plate on the package substrate such that the first surface of the plate faces the first surface of the package substrate and the stiffener is connected to the first surface of the package substrate, bonding the first surface of the plate to the first adhesive layer, and removing the plate. After removing the plate, the stiffener remains connected to the first surface of the package substrate.

### CROSS-REFERENCE TO RELATED APPLICATION

This application claims the benefit of priority under 35 U.S.C. § 119 to Korean Patent Application No. 10-2024-0061383, filed on May 9, 2024, in the Korean Intellectual Property Office, the disclosure of which is incorporated herein by reference.

### BACKGROUND

The present disclosure relates to a method for manufacturing a semiconductor package and a semiconductor package manufactured by using the same.

With development of electronic industry, a demand for high functionalization, high speed, and miniaturization of an electronic component is increasing. To correspond to such a trend, a method of stacking and mounting multiple semiconductor chips on one package wiring structure or a method of stacking a package on another package may be used.

Meanwhile, a highly integrated semiconductor package may have difficulty with regulating heat, and warpage may occur due to a thermal expansion rate difference occurring in a semiconductor manufacturing process or heat occurring inside the semiconductor package. A stiffener may prevent the warpage of the semiconductor package. A heat slug may be used to regulate the heat of the semiconductor package by dissipating heat from the semiconductor package. Meanwhile, the heat slug which is disposed on a semiconductor chip may be effective in warpage prevention similarly to the stiffener. In addition, when other types of heat regulation is used in combination with a heat slug or a stiffener, the stiffener may be more effective in the heat dissipation when compared to the heat slug. For example, in a case of heat regulation by natural convection, the heat slug may be effective in the heat dissipation. In a case of heat regulation by forced convection such as heat regulation through a fan or liquid immersion cooling, the stiffener may be more effective in the heat dissipation than the heat slug.

### SUMMARY

An aspect of the present disclosure provides a method of manufacturing a semiconductor package having improved warpage resistance and an improved heat dissipation characteristic.

Another aspect of the present disclosure also provides a semiconductor package having improved warpage resistance and an improved heat dissipation characteristic.

However, the goals to be achieved by example embodiments of the present disclosure are not limited to the objectives described above and other objects may be clearly understood from the following example embodiments by those skilled in the art.

According to an aspect of the present disclosure, there is provided a method for manufacturing a semiconductor package, the method including mounting a first semiconductor chip on a first surface of a package substrate, forming a stiffener on a first surface of a plate, forming a first adhesive layer on the first semiconductor chip, disposing the stiffener and the plate on the package substrate such that the first surface of the plate faces the first surface of the package substrate and the stiffener is connected to the first surface of the package substrate, bonding the first surface of the plate to the first adhesive layer, and removing the plate, wherein the stiffener remains connected to the first surface of the package substrate subsequent to removing the plate.

According to another aspect of the present disclosure, there is provided a method for manufacturing a semiconductor package, the method including forming a stiffener along an edge of a first surface of a plate, mounting a first semiconductor chip on a first surface of the package substrate, disposing the stiffener and the plate on the package substrate so that the first surface of the plate faces the first semiconductor chip and so that the stiffener surrounds a side surface of the first semiconductor chip, and removing the plate, wherein the stiffener remains on the package substrate subsequent to removing the plate, and wherein a thermal conductivity of the plate is less than a thermal conductivity of the stiffener.

According to still another aspect of the present disclosure, there is provided a semiconductor package including a package substrate, a first semiconductor chip disposed on a first surface of the package substrate, and a stiffener disposed on the first surface of the package substrate to be spaced apart from the first semiconductor chip and to surround the first semiconductor chip, and an upper surface of the stiffener and an upper surface of the first semiconductor chip are disposed on an identical plane, and the stiffener includes a recess formed on the upper surface of the stiffener.

Additional aspects of example embodiments will be set forth in part in the following description.

According to example embodiments, it is possible to manufacture a semiconductor package having improved warpage resistance and an improved heat dissipation characteristic.

According to example embodiment, it is possible to improve warpage resistance of a semiconductor package and improve a heat dissipation characteristic of the semiconductor package.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIGS. 1 through 6 are intermediate operation diagrams illustrating a method for manufacturing a semiconductor package according to an example embodiment;

FIG. 7 is an intermediate operation diagram illustrating a method for manufacturing a semiconductor package according to an example embodiment;

FIG. 8 is an intermediate operation diagram illustrating a method for manufacturing a semiconductor package according to an example embodiment;

FIG. 9 is an intermediate operation diagram illustrating a method for manufacturing a semiconductor package according to an example embodiment;

FIG. 10 is an intermediate operation diagram illustrating a method for manufacturing a semiconductor package according to an example embodiment;

FIGS. 11 and 12 are intermediate operation diagrams illustrating a method for manufacturing a semiconductor package according to an example embodiment;

FIG. 13 is an intermediate operation diagram illustrating a method for manufacturing a semiconductor package according to an example embodiment;

FIG. 14 is an intermediate operation diagram illustrating a method for manufacturing a semiconductor package according to an example embodiment; and

FIGS. 15 through 17 are intermediate operation diagrams illustrating a method for manufacturing a semiconductor package according to an example embodiment.

### DETAILED DESCRIPTION

Before example embodiments are described, terms or words used in the present disclosure and the accompanying claims are not to be limited to general definitions or dictionary definitions. The terms and words are to be construed under a principle that an inventor may appropriately define a concept of a term in order to describe their invention in the best way. Thus, since the example embodiments described in the present disclosure and configurations illustrated in the accompanying drawings are merely most desirable example embodiments and do not represent all of the technical spirit of the present disclosure, it should be understood that various equivalents and modifications that may replace the example embodiments and configurations may be present at the time of filing the application of the present disclosure.

In the following descriptions, terms in a singular form includes terms a plural form unless an apparently and contextually conflicting description is present. Terms such as “including” or “comprising” is to indicate that a feature, a number, an operation, an action, an element, a component, or a combination thereof is present. It should be understood that the terms are not to exclude in advance a possibility that one or more other features, numbers, operations, actions, elements, components, or combinations thereof may be present or added.

In addition, it should be noted in advance that an expression such as an upper side, an upper portion, a lower side, a lower portion, a side surface, a front surface, or a rear surface is based on directions illustrated in the drawings and that the expression may be changed when a direction of a corresponding object is changed. Shapes, sizes, or the like of elements in the drawings may be exaggerated for clearer description.

Hereinafter, the example embodiments of the present disclosure will be described with reference to the drawings.

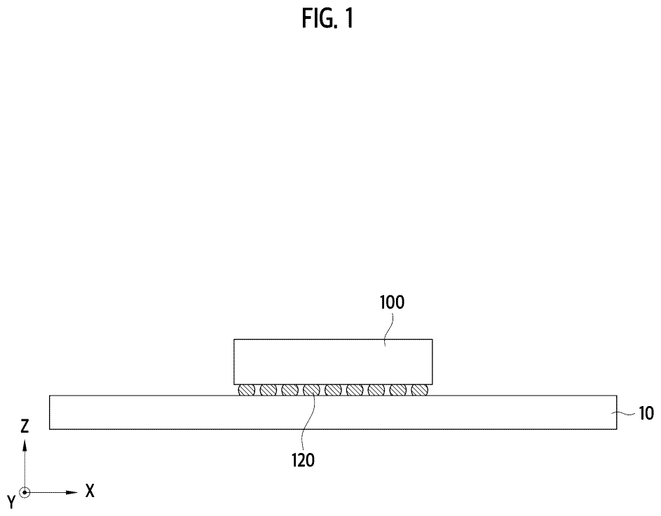

FIGS. 1 through 6 are intermediate operation diagrams illustrating a method for manufacturing a semiconductor package according to an example embodiment.

Referring to FIG. 1, the method for manufacturing the semiconductor package according to example embodiments of the present disclosure may include mounting a first semiconductor chip 100 on a package substrate 10.

According to some example embodiments, the package substrate 10 may be, for example, a printed circuit board (PCB), a ceramic substrate, or an interposer. Alternatively, the package substrate 10 may be a semiconductor chip including a semiconductor device. The package substrate 10 may function as a support substrate for the semiconductor package. The package substrate 10 may extend in a first direction X and a second direction Y

In some example embodiments, the package substrate 10 may be a glass substrate, the ceramic substrate, or a plastic substrate, but it is merely an example. For example, the package substrate 10 may include a resin (e.g., prepreg, Ajinomoto Build-up Film (ABF), FR-4, or bismaleimide triazine (BT)) impregnated together with an inorganic filler in a core material such as a glass fiber (e.g., a glass cloth or a glass fabric).

According to some example embodiments, the package substrate 10 may be, as an example, a bulk silicon substrate or a silicon-on-insulator (SOI) substrate. As another example, the package substrate 10 may be a silicon substrate. As still another example, the package substrate 10 may include silicon germanium, a silicon germanium on insulator (SGOI), indium antimonide, lead telluride, indium arsenide, indium phosphide, gallium arsenide, or gallium antimonide, but it is merely an example.

According to some example embodiments, the package substrate 10 may include a well doped with an impurity or a structure doped with an impurity. The package substrate 10 may have various element separation structures such as a shallow trench isolation (STI) structure.

In some example embodiments, the package substrate 10 may be formed from at least one material selected from a phenolic resin, an epoxy resin, and polyimide. The package substrate 10 may include at least one material selected from tetrafunctional epoxy, polyphenylene ether, epoxy/polyphenylene oxide, bismaleimide triazine, Thermount, cyanate ester, and a liquid crystal polymer.

Although not illustrated in detail, the package substrate 10 may include a substrate body, a lower surface pad, and an upper surface pad. Wiring patterns for electrically connecting the lower surface pad and the upper surface pad may be formed in the substrate body. The lower surface pad may be disposed on a lower surface of the substrate body. The upper surface pad may be disposed on an upper surface of the substrate body. An external connection terminal may be disposed on the lower surface pad. For example, the external connection terminal may be a solder ball or a bump.

According to some example embodiment, a first semiconductor chip 100 may be disposed on the package substrate 10. For example, the first semiconductor chip 100 may be mounted on an upper surface of the package substrate 10. The first semiconductor chip 100 may be mounted on the package substrate 10 through a flip chip bonding method. The first semiconductor chip 100 may be bonded on the package substrate 10 by using a connection bump 120. The connection bump 120 may be formed between the upper surface of the package substrate 10 and a lower surface of the first semiconductor chip 100. The connection bump 120 may electrically connect the first semiconductor chip 100 and the package substrate 10.

According to some example embodiments, the first semiconductor chip 100 may be an integrated circuit (IC) in which hundreds or thousands of semiconductor devices are integrated in one chip. As an example, the first semiconductor chip 100 may be an application processor (AP) such as a central processing unit (CPU), a graphic processing unit (GPU), a field-programmable gate array, a digital signal processor, a cryptographic processor, a microprocessor, or a microcontroller. However, it is merely an example.

As another example, the first semiconductor chip 100 may be a logic chip such as an analog-digital converter (ADC) or an application-specific IC (ASIC) or may be a memory chip such as a volatile memory (e.g., a dynamic random access memory (DRAM)) or a non-volatile memory (e.g., a read-only memory (ROM), or a flash memory). In addition, the first semiconductor chip 100 may be configured in combination thereof.

According to some example embodiments, only one first semiconductor chip 100 is illustrated as being formed on the package substrate 10, but this is merely for convenience of description. For example, a plurality of semiconductor chips may be formed side by side on the package substrate 10 or sequentially stacked on the on the package substrate 10.

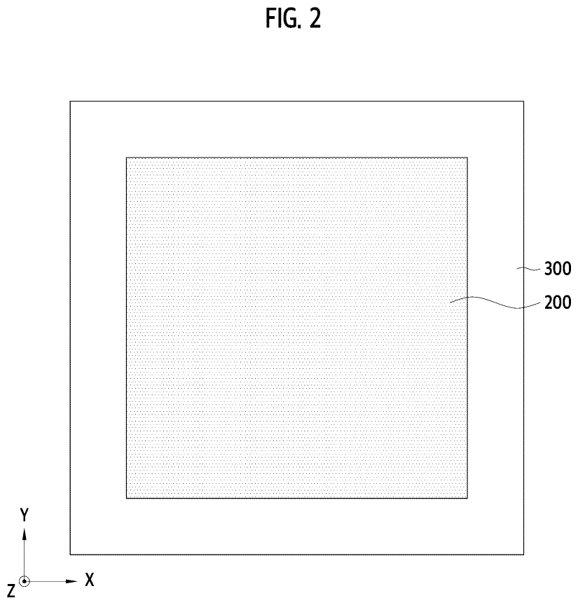

Then, referring to FIG. 2, the method for manufacturing the semiconductor package according to example embodiments of the present disclosure may include forming a stiffener 300 on a plate 200.

According to some example embodiments, the stiffener 300 may be formed on one surface of the plate 200. The stiffener 300 may be formed along an edge of the plate 200. For example, the stiffener 300 may be disposed along the edge of the plate 200 which extends in the first direction X and the second direction Y. In other words, the stiffener 300 may have a shape of a quadrangular ring when viewed from a plan view. A portion of the one surface of the plate 200 may be exposed through a gap of the stiffener 300 which extends in the first direction X and the second direction Y.

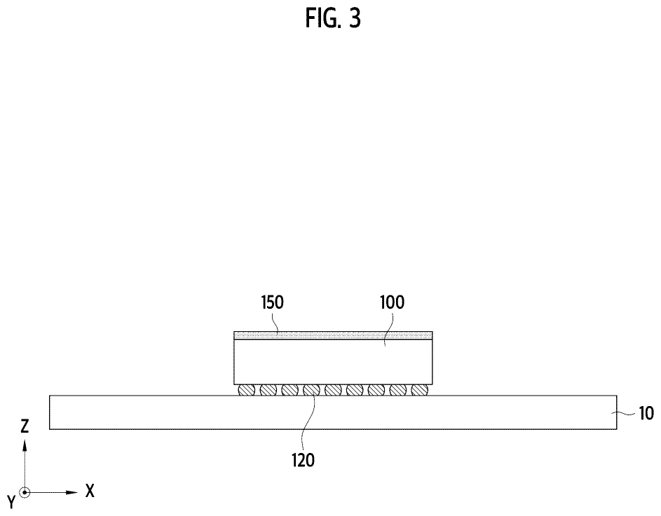

Referring to FIG. 3, the method for manufacturing the semiconductor package according to example embodiments of the present disclosure may include forming a first adhesive layer 150 on the upper surface of the first semiconductor chip 100. The first adhesive layer 150 may cover the upper surface of the first semiconductor chip 100. The first adhesive layer 150 may include a material identical to that of a second adhesive layer 350 that will be described below. For example, the first adhesive layer 150 may include a pyrolytic or photolytic material.

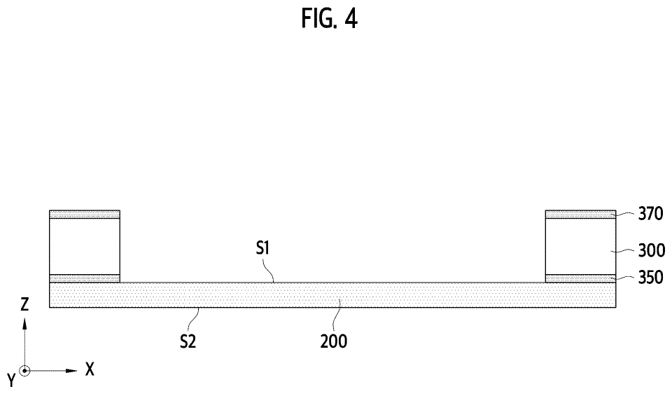

Referring to FIG. 4, according to some example embodiments, the plate 200 may include a first surface S1 and a second surface S2. A surface on which the stiffener 300 is formed may be referred to as the first surface S1. For example, the one surface of the plate 200 on which the stiffener 300 is formed, as described above through FIG. 2, may be the first surface S1. A surface disposed opposite to the first surface S1 may be referred to as the second surface S2. A height of the first surface S1 may be constant from the second surface S2 of the plate 200. The first surface S1 may not have a step difference. A thickness of the plate 200, between the first surface S1 and the second surface S2, may be constant in the first direction X. A thickness and a height, as described herein, may be measured in a third direction Z.

The plate 200 may include, for example, copper (Cu), iron (Fe), nickel (Ni), cobalt (Co), tungsten (W), chromium (Cr), silver (Ag), gold (Au), platinum (Pt), tin (Sn), aluminum (Al), magnesium (Mg), silicon (Si), zinc (Zn), or a combination thereof. As another example, the plate 200 may include a non-metallic substance. The plate 200 may include stainless steel (SUS), or plastic. A thermal conductivity of the plate 200 may be less than or equal to a thermal conductivity of the stiffener 300.

As an example, the stiffener 300 may include metal such as copper (Cu). As another example, the stiffener 300 may include a material identical to that of the package substrate 10. The stiffener 300 and the plate 200 may include an identical material. For example, the stiffener 30 and the plate 200 each may include copper (Cu). In contrast, the stiffener 300 and the plate 200 may include different materials. For example, the plate 200 may include plastic, and the stiffener 300 may include copper (Cu).

According to some example embodiments, the stiffener 300 may be bonded onto the first surface S1 of the plate through the second adhesive layer 350. The second adhesive layer 350 may be formed between the stiffener 300 and the plate 200.

According to some example embodiments, the second adhesive layer 350 may include a pyrolytic or photolytic material. For example, the second adhesive layer 350 may include a pyro/photolytic epoxy resin or titanium. However, it is merely an example. The second adhesive layer 350 may include a polymer, a resin, or a thermal interface material (TIM) including epoxy and a filling material. The filling material may include a dielectric filling material such as aluminum oxide, magnesium oxide, aluminum nitride, boron nitride, and diamond power. Also, the filling material may be a metallic filling material such as silver, copper, or aluminum.

According to some example embodiments, a third adhesive layer 370 may be formed on one surface of the stiffener 300, which is disposed opposite to a surface, of the stiffener 300, facing the plate 200. The third adhesive layer 370 may include a material different from that of the second adhesive layer 350. For example, the third adhesive layer 370 may include a non-pyrolytic or non-photolytic material. The third adhesive layer 370 may include a polymer, a resin, or a TIM including epoxy and a filling material. The filling material may include a dielectric filling material such as aluminum oxide, magnesium oxide, aluminum nitride, boron nitride, and diamond powder. The filling material may be a metal filling material such as silver, copper, or aluminum.

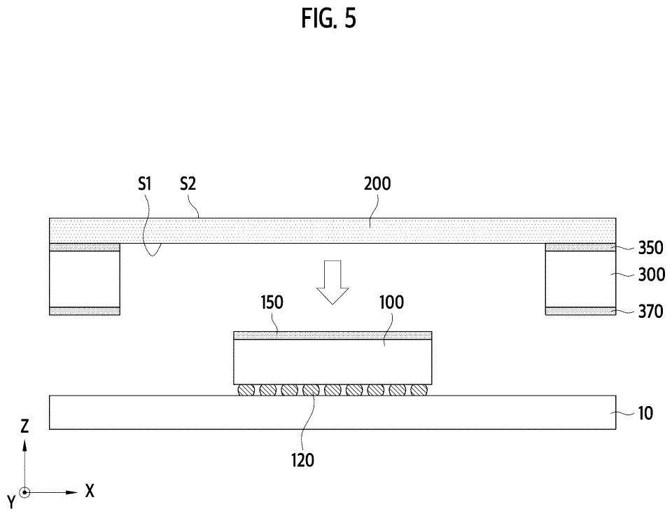

Then, referring to FIG. 5, the method for manufacturing the semiconductor package according to example embodiments of the present disclosure may include arranging the plate 200 and the stiffener 300 on the package substrate 10.

According to some example embodiments, the plate 200 and the stiffener 300 may be arranged on the package substrate 10 so that the first surface S1 of the plate faces the package substrate 10. The stiffener 300 may be arranged so as to protrude from the first surface S1 of the plate toward the package substrate 10.

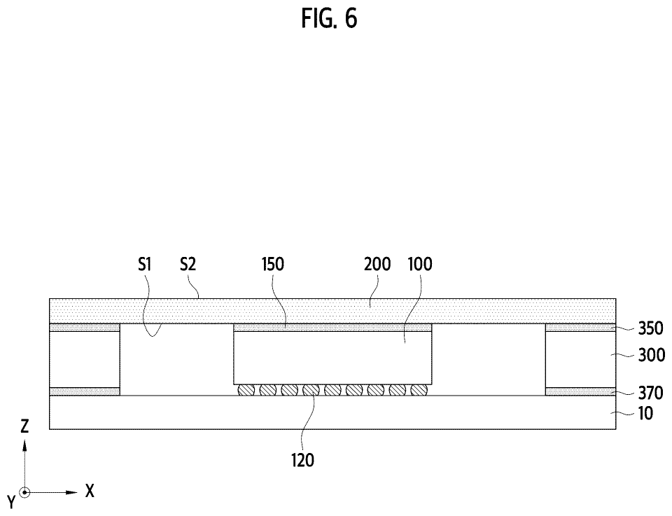

Then, referring to FIG. 6, the method for manufacturing the semiconductor package according to example embodiments of the present disclosure may include disposing the plate 200 and the stiffener 300 on the package substrate 10.

According to some example embodiments, the first surface S1 of the plate 200 may be bonded to the first adhesive layer 150 on the first semiconductor chip 100. The plate 200 may be formed on the first semiconductor chip 100 and the stiffener 300. The plate 200 may overlap the first semiconductor chip 100 and the stiffener 300 in the third direction Z. The third direction Z may be a direction perpendicular to the upper surface of the package substrate 10.

According to some example embodiments, the stiffener 300 may be bonded onto the package substrate 10 through the third adhesive layer 370. The stiffener 300 may be disposed on the package substrate 10 to surround a side surface of the first semiconductor chip 100. The stiffener 300 may be disposed to be spaced apart from the first semiconductor chip 100. For example, the first semiconductor chip 100 may be disposed in the quadrangular ring shape which is formed by the stiffener 300 when viewed from the plan view.

According to some example embodiments, the semiconductor package may include the plate 200 and the stiffener 300. The semiconductor package which includes all of the plate 200 and the stiffener 300 may have an improved warpage resistance characteristic. For example, the stiffener 300 may suppress occurrence of warpage at an edge of the package substrate 10. In addition, the plate 200 which is disposed to overlap the first semiconductor chip 100, which is disposed in the gap of the stiffener 300, may suppress occurrence of warpage inside the stiffener 300. Also, heat occurring inside the semiconductor package may be transferred through the stiffener 300 and the plate 200 and easily dissipated to an outside (e.g., external to the semiconductor package).

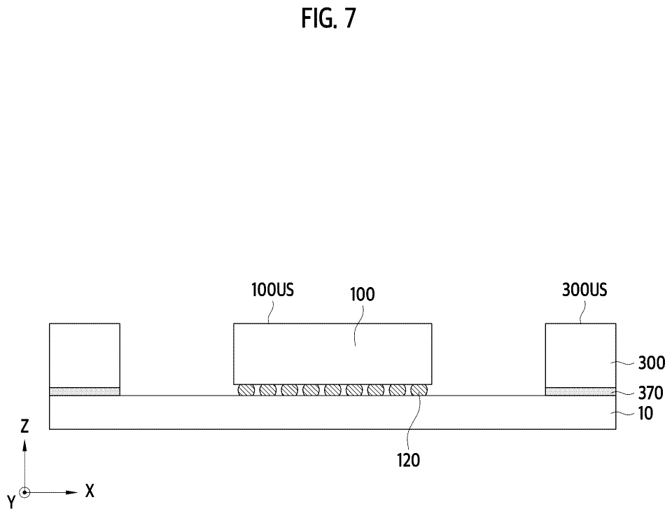

FIG. 7 is an intermediate operation diagram illustrating a method for manufacturing a semiconductor package according to an example embodiment. For convenience of description, the following description mainly focuses on a point different from that described with reference to FIGS. 1 through 6. For reference, FIG. 7 is a diagram for describing an operation after that of FIG. 6.

Referring to FIG. 7, the method for manufacturing the semiconductor package according to example embodiments of the present disclosure may further include removing the plate 200 (of FIG. 6).

According to some example embodiments, the removing of the plate 200 (of FIG. 6) may include removing the first adhesive layer 150 (of FIG. 6) and the second adhesive layer 350 (of FIG. 6). As the plate 200 (of FIG. 6) is removed, the first adhesive layer 150 (of FIG. 6) and the second adhesive layer 350 (of FIG. 6) may be removed together. For example, the first adhesive layer 150 (of in FIG. 6) and the second adhesive layer 350 (of FIG. 6) may be removed with heat or light. As the plate 200 (of FIG. 6) is removed, an upper surface of the first semiconductor chip 100US and an upper surface of the stiffener 300US may be exposed.

According to some example embodiments, from a first surface of the package substrate 10, which faces the first semiconductor chip 100, a height of the first semiconductor chip 100 and a height of the stiffener 300 may be equal. Specifically, from an upper surface of the package substrate 10, a height of the upper surface of the first semiconductor chip 100US and a height of the upper surface of the stiffener 300US may be equal.

According to some example embodiments, the plate 200 (of FIG. 6) may suppress warpage of a portion of the semiconductor package to which the first semiconductor chip 100 is disposed in a gap of the stiffener 300. For example, an area in which the first semiconductor chip 100 is disposed inside the stiffener 300 may have a high possibility of the warpage because the first semiconductor chip 100 and the package substrate 10 are exposed. Meanwhile, the plate 200 (of FIG. 6), which is formed to cover the first semiconductor chip 100, may improve warpage resistance of the semiconductor package by fixing the first semiconductor chip 300 in the gap of the stiffener 300 in the third direction Z. Thus, occurrence of the warpage or twist of the semiconductor package in a semiconductor package manufacturing process may be suppressed with the plate 200 (of FIG. 6). In addition, the stiffener 300 may have a thermal conductivity higher than that of the plate 200 (of FIG. 6). Accordingly, by removing the plate 200 (of FIG. 6) and exposing the stiffener 300 after a manufacturing process having a condition that may allow the semiconductor package to be warped or twisted is ended, heat occurring in the semiconductor package may be easily dissipated through the stiffener 300.

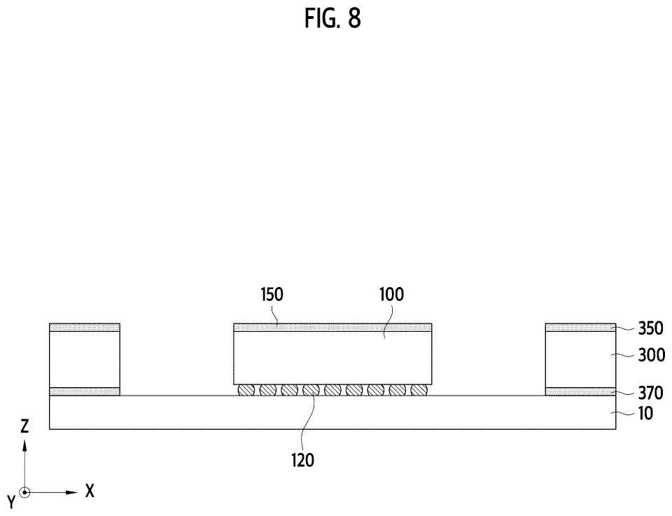

FIG. 8 is an intermediate operation diagram illustrating a method for manufacturing a semiconductor package according to an example embodiment. For convenience of description, the following description mainly focuses on a point different from that described with reference to FIGS. 1 through 6. For reference, FIG. 8 corresponds to an intermediate operation diagram illustrated in FIG. 7.

Referring to FIGS. 6 and 8, the first adhesive layer 150 and the second adhesive layer 350 may not be removed when the plate 200 is removed. As the plate 200 is removed, the first adhesive layer 150 and the second adhesive layer 350 may be exposed. For example, after the plate 200 is removed, the first adhesive layer 150 may remain on the first semiconductor chip 100. After the plate 200 is removed, the second adhesive layer 350 may remain on the stiffener 300.

FIG. 8 illustrates that all of the first adhesive layer 150 and the second adhesive layer 350 are not removed and remain, but it is merely an example. As an example, as the plate 200 is removed, the first adhesive layer 150 may be also removed, and only the second adhesive layer 350 may remain on the stiffener 300. As another example, as the plate 200 is removed, the second adhesive layer 350 may be removed, and the first adhesive layer 150 may remain on the first semiconductor chip 100.

Furthermore, the first adhesive layer 150 and the second adhesive layer 350 may not remain as being in an initial state in which each is formed, may be partially removed, and may partially remain. As an example, as the plate 200 is removed, the first adhesive layer 150 may be partially removed, and a thickness of the first adhesive layer 150 remaining on the first semiconductor chip 100 may be reduced. As another example, as the plate 200 is removed, the second adhesive layer 350 may be partially removed, and a thickness of the second adhesive layer 350 remaining on the stiffener 300 may be reduced.

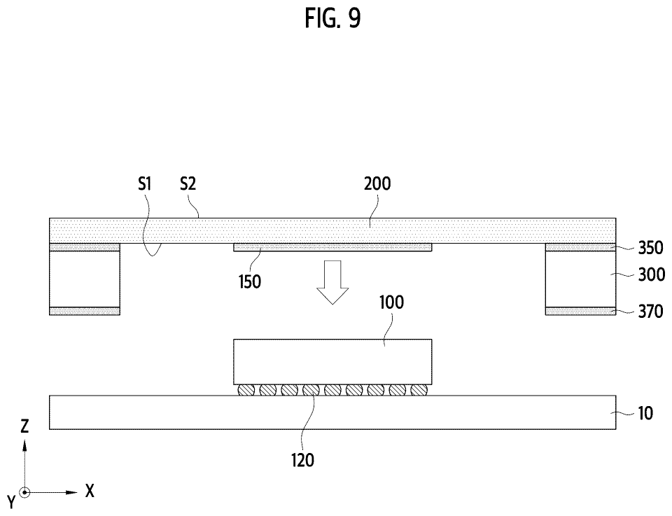

FIG. 9 is an intermediate operation diagram illustrating a method for manufacturing a semiconductor package according to an example embodiment. For convenience of description, the following description mainly focuses on a point different from that described with reference to FIGS. 1 through 6. For reference, FIG. 9 corresponds to an intermediate operation diagram illustrated in FIG. 5.

Referring to FIG. 9, the first adhesive layer 150 may be formed on the plate 200. For example, the first adhesive layer 150 may be formed on the first surface S1 of the plate 200. The first adhesive layer 150 may be formed at a position corresponding to the first semiconductor chip 100 on the first surface S1 of the plate 200.

The plate 200 to which the first adhesive layer 150 and the stiffener 300 are formed according to another example embodiment may be disposed to overlap the first semiconductor chip 100 on the package substrate 10. The plate 200 may be bonded onto the first semiconductor chip 100 through the first adhesive layer 150 formed on the first surface S1.

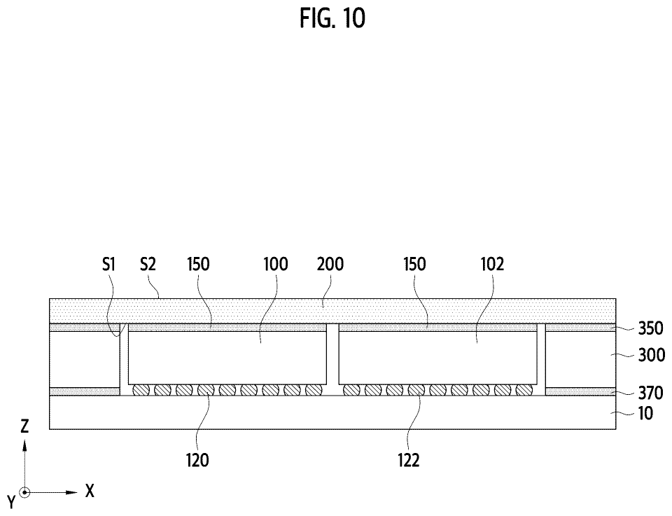

FIG. 10 is an intermediate operation diagram illustrating a method for manufacturing a semiconductor package according to an example embodiment. For convenience of description, the following description mainly focuses on a point different from that described with reference to FIGS. 1 through 7. For reference, FIG. 10 corresponds to an intermediate operation diagram illustrated in FIG. 6.

Referring to FIG. 10, the method for manufacturing the semiconductor package according to example embodiments of the present disclosure may include mounting the first semiconductor chip 100 and a second semiconductor chip 102 on the package substrate 10. In addition, the method for manufacturing the semiconductor package may include further forming the first adhesive layer 150 on the second semiconductor chip 102. The plate 200 may be bonded onto the first semiconductor chip 100 and the second semiconductor chip 102 through the first adhesive layer 150. The stiffener 300 may be disposed to surround the first semiconductor chip 100 and the second semiconductor chip 102.

Since an operation other than an operation illustrated in FIG. 10 is substantially identical to intermediate operations described with reference to FIGS. 1 through 7, a description thereof will be omitted.

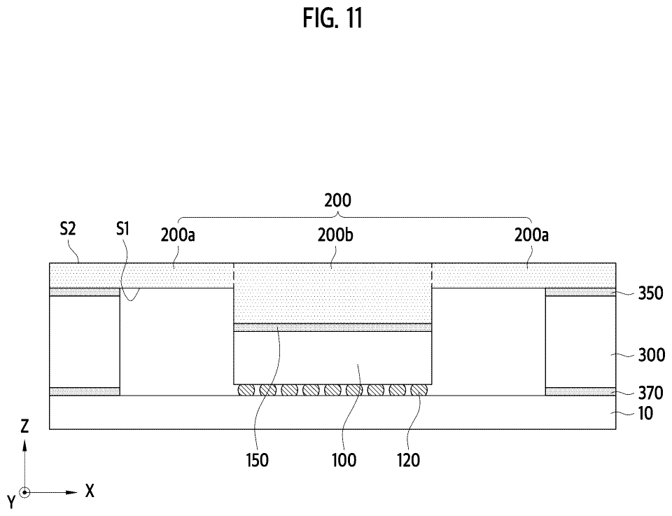

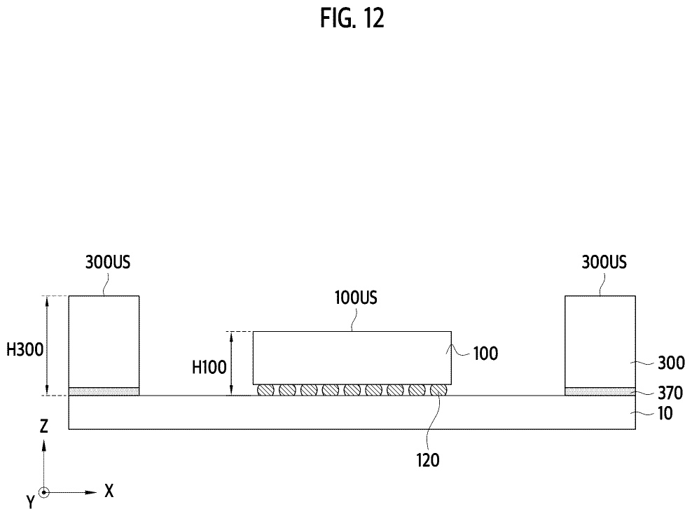

FIGS. 11 and 12 are intermediate operation diagrams illustrating a method for manufacturing a semiconductor package according to an example embodiment. For convenience of description, the following description mainly focuses on a point different from that described with reference to FIGS. 1 through 7. For reference, FIGS. 11 and 12 correspond to intermediate operation diagrams illustrated in FIG. 6 and FIG. 7, respectively.

Referring to FIG. 11, the plate 200 may include a first portion 200a and a second portion 200b. A portion of the plate 200, to which the stiffener 300 is formed, may be referred to as the first portion 200a. The first portion 200a may be bonded to the stiffener 300 through the second adhesive layer 350.

According to some example embodiments, the second portion 200b may be disposed in a gap of the first portion 200a and protrude further in the third direction Z than the first portion 200a. The second portion 200b may overlap the first semiconductor chip 100 in the third direction Z. The second portion 200b may be bonded to the first semiconductor chip 100 through the first adhesive layer 150. In the first direction X, a width of the second portion 200b may be equal to a width of the first semiconductor chip 100. However, it is merely an example. For example, in the first direction X, the width of the second portion 200b may be less than the width of the first semiconductor chip 100.

According to some example embodiments, the plate 200 may have an inconstant thickness in the first direction X. A thickness of the first portion 200a may be less than a thickness of the second portion 200b. A height of the first surface S1 from the second surface S2 of the plate 200 may be inconstant. For example, from the second surface S2 of the plate 200, a height of the first surface S1 of the first portion 200a may be less than a height of the first surface S1 of the second portion 200b.

Referring to FIG. 12, the upper surface of the first semiconductor chip 100US and the upper surface of the stiffener 300US may be exposed after the plate 200 (of FIG. 11) is removed.

According to some example embodiments, from the first surface of the package substrate 10, facing the first semiconductor chip 100, a height of the first semiconductor chip H100 and a height of the stiffener H300 may not be equal to each other. A distance from the first surface of the package substrate 10 to the upper surface of the first semiconductor chip 100US may be referred to as the height of the first semiconductor chip H100. A distance from the first surface of the package substrate 10 to the upper surface of the stiffener 300US may be referred to as the height of the stiffener H300. The height of the stiffener H300 may be greater than the height of the first semiconductor chip H100.

According to some example embodiments, in the plate 200 (of FIG. 11), a portion overlapping the first semiconductor chip 100 and a portion overlapping the stiffener 300 may be formed to have different thicknesses even if the first semiconductor chip 100 and the stiffener 300 have different heights. Through this, by using the plate 200 (of FIG. 11), the first semiconductor chip 100 and the stiffener 300 may be strongly mounted on the package substrate 10, and twist of the semiconductor package may be suppressed.

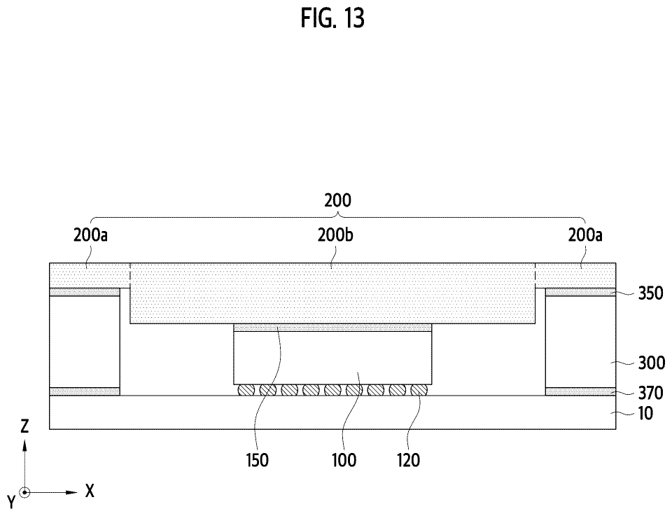

FIG. 13 is an intermediate operation diagram illustrating a method for manufacturing a semiconductor package according to an example embodiment. For convenience of description, the following description mainly focuses on a point different from that described with reference to FIG. 11.

Referring to FIG. 13, the second portion 200b which overlaps the first semiconductor chip 100 in the third direction Z may have a width greater than a width of the first semiconductor chip 100 in the first direction X. Since the second portion 200b which has a thickness greater than that of the first portion 200a overlaps a gap space in which the first semiconductor chip 100 and the stiffener 300 are spaced apart from each other, resistance to twist of the semiconductor package may be further improved in a semiconductor package manufacturing process.

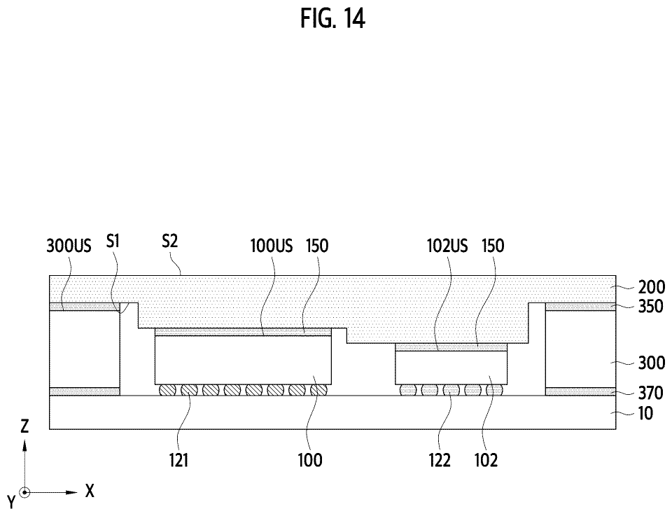

FIG. 14 is an intermediate operation diagram illustrating a method for manufacturing a semiconductor package according to an example embodiment. For convenience of description, the following description mainly focuses on a point different from that described with reference to FIG. 10.

Referring to FIG. 14, the stiffener 300, the first semiconductor chip 100, and the second semiconductor chip 102 may have different heights. The upper surface of the first semiconductor chip 100US, an upper surface of the second semiconductor chip 102US, and the upper surface of the stiffener 300US may have different heights from the first surface of the package substrate 10. For example, from the first surface of the package substrate 10, a height of the upper surface of the stiffener 300US may be greater than a height of the upper surface of the first semiconductor chip 100US and a height of the upper surface of the second semiconductor chip 102US. For example, from the first surface of the package substrate 10, the height of the upper surface of the second semiconductor chip 102US may be less than the height of the upper surface of the stiffener 300US and the height of the upper surface of the first semiconductor chip 100US.

According to some example embodiments, a portion of the plate 200 overlapping the stiffener 300, a portion of the plate 200 overlapping the first semiconductor chip 100, and a portion of the plate 200 overlapping the second semiconductor 102 may have different thicknesses.

According to some example embodiments, the first surface S1 of the plate 200 may include a portion bonded to the stiffener 300 through the second adhesive layer 350, a portion bonded to the first semiconductor chip 100 through the first adhesive layer 150, and a portion bonded to the second semiconductor chip 102 through the first adhesive layer 150. From the second surface S2 of the plate 200, a height of the first surface S1 which overlaps the stiffener 300 may be less than a height of the first surface S1 which overlaps the first semiconductor chip 100 and a height of the first surface S1 which overlaps the second semiconductor chip 102. From the second surface S2 of the plate 200, the height of the first surface S1 which overlaps the second semiconductor chip 102 may be greater than the height of the first surface S1 which overlaps the stiffener 300 and the height of the first surface S1 which overlaps the first semiconductor chip 100.

According to some example embodiments, although the first semiconductor chip 100, the second semiconductor chip 102, and the stiffener 300 which are disposed on the package substrate 10 have heights different from each other, thicknesses of portions of the plate 200, respectively overlapping the first semiconductor chip 100, the second semiconductor chip 102, and the stiffener 300 may be adjusted so that the plate 200 is disposed on the first semiconductor chip 100, the second semiconductor chip 102, and the stiffener 300 through the second adhesive layer 350 and the first adhesive layer 150. Through this, twist that may occur in a semiconductor package manufacturing process may be effectively suppressed.

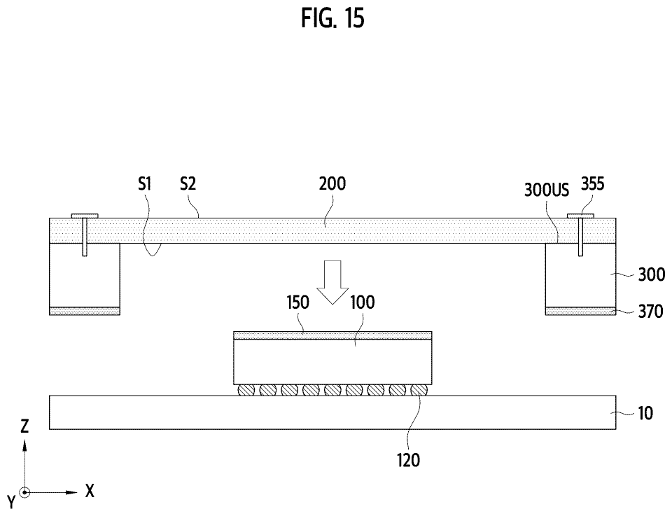

FIGS. 15 through 17 is an intermediate operation diagram illustrating a method for manufacturing a semiconductor package according to an example embodiment. For convenience of description, the following description mainly focuses on a point different from that described with reference to FIGS. 1 through 7. For reference, FIGS. 15 through 17 correspond to intermediate operation diagrams illustrated in FIGS. 5 through 7.

Referring to FIG. 15, the plate 200 and the stiffener 300 may be connected through a fastening part (e.g., fastener) 355. The fastening part 355 may penetrate the plate 200 and be partially inserted into the stiffener 300. The fastening part 355 may have a fastening structure such as a screw bolt or a pin. Since the plate 200 and the stiffener 300 are connected through the fastening part 355, the second adhesive layer 350 (of FIG. 5) may not be disposed between the first surface S1 of the plate 200 and the upper surface of the stiffener 300US. The first surface S1 of the plate 200 and the upper surface of the stiffener 300US may contact each other. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

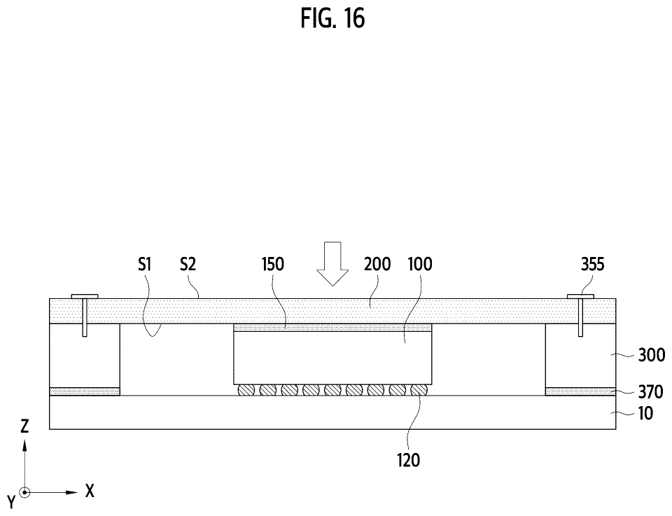

Referring to FIG. 16, the plate 200 and the stiffener 300 connected through the fastening part 355 may be disposed on the package substrate 10.

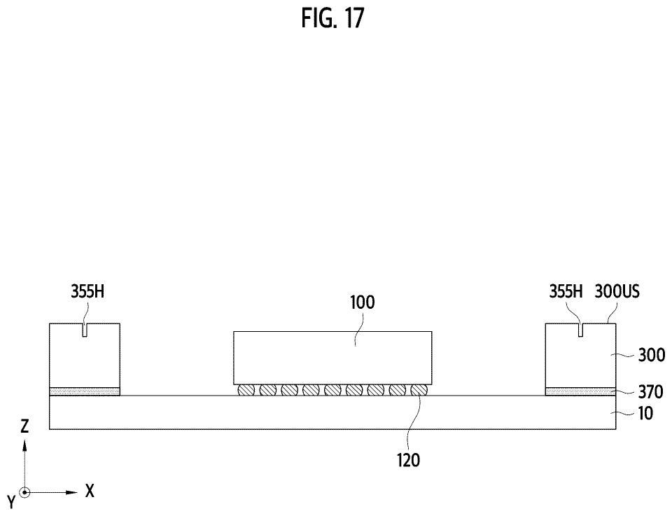

Referring to FIG. 17, the upper surface of the stiffener 300US may be exposed by removing the fastening part 355 (of FIG. 16) and the plate 200 (of FIG. 16). Also, the stiffener 300 may include a recess 355H corresponding to the fastening part 355 (of FIG. 16). For example, in the method for manufacturing the semiconductor package, removing the plate 200 (of FIG. 16) may include removing the fastening part 355 (of FIG. 16) and exposing the recess 355H in which the fastening part 355 (of FIG. 16) had been partially inserted into the stiffener 300.

The various example embodiments of the present disclosure have been described in detail above, but the scope of the present disclosure is not limited thereto. It will be apparent to those skilled in the art that various changes and modifications may be allowed within the scope of the technical spirit of the present disclosure. In addition, the above-described example embodiments may be implemented without a portion of elements thereof, and each of the example embodiments may be implemented in combination with another.

What is claimed is:

1. A method for manufacturing a semiconductor package, the method comprising:
mounting a first semiconductor chip on a first surface of a package substrate;
forming a stiffener on a first surface of a plate;
forming a first adhesive layer on the first semiconductor chip;
disposing the stiffener and the plate on the package substrate such that the first surface of the plate faces the first surface of the package substrate and the stiffener is connected to the first surface of the package substrate;
bonding the first surface of the plate to the first adhesive layer; and
removing the plate,
wherein the stiffener remains connected to the first surface of the package substrate subsequent to removing the plate.

2. The method of claim 1, wherein the removing of the plate comprises removing the first adhesive layer on the first semiconductor chip.

3. The method of claim 1, wherein from the first surface of the package substrate, a height of an upper surface of the stiffener is equal to a height of an upper surface of the first semiconductor chip.

4. The method of claim 1, wherein the plate includes a second surface disposed opposite to the first surface of the plate, and
a height of the first surface of the plate is constant from the second surface of the plate.

5. The method of claim 1, wherein the forming of the stiffener on the first surface of the plate comprises bonding the first surface of the plate and the stiffener with a second adhesive layer.

6. The method of claim 1, wherein the forming of the stiffener on the first surface of the plate comprises connecting the stiffener and the plate by using a fastener penetrating the plate and partially inserted into the stiffener.

7. The method of claim 6, wherein the removing of the plate comprises:
removing the fastener; and
exposing a recess in which the fastener had been partially inserted into the stiffener.

8. The method of claim 1, wherein from the first surface of the package substrate on which the first semiconductor chip is mounted, a height of the stiffener is higher than a height of the first semiconductor chip, and
the plate includes:
a first portion to which the stiffener is formed; and
a second portion having a thickness greater than the first portion.

9. The method of claim 8, wherein a width of the second portion is greater than a width of the first semiconductor chip.

10. The method of claim 1, wherein a thermal conductivity of the plate is less than or equal to a thermal conductivity of the stiffener.

11. The method of claim 1, wherein the disposing of the stiffener on the package substrate comprises disposing the stiffener on the package substrate to surround the first semiconductor chip.

12. The method of claim 1, further comprising:
mounting a second semiconductor chip on the package substrate to be spaced apart from the first semiconductor chip; and
further forming the first adhesive layer on the second semiconductor chip.

13. A method for manufacturing a semiconductor package, the method comprising:
forming a stiffener along an edge of a first surface of a plate;
mounting a first semiconductor chip on a first surface of a package substrate;
disposing the stiffener and the plate on the package substrate so that the first surface of the plate faces the first semiconductor chip and so that the stiffener surrounds a side surface of the first semiconductor chip; and
removing the plate,
wherein the stiffener remains on the package substrate subsequent to removing the plate, and
wherein a thermal conductivity of the plate is less than a thermal conductivity of the stiffener.

14. The method of claim 13, further comprising forming a first adhesive layer on an upper surface of the first semiconductor chip which faces the first surface the plate,
wherein the disposing of the stiffener and the plate on the package substrate comprises bonding the first surface of the plate onto the first adhesive layer.

15. The method of claim 13, wherein the removing of the plate comprises exposing one surface of the stiffener which faces the first surface of the plate.

16. The method of claim 13, wherein from the first surface of the package substrate on which the first semiconductor chip is mounted, a height of the stiffener is higher than a height of the first semiconductor chip, and
the plate includes:
a first portion to which the stiffener is formed; and
a second portion having a thickness greater than the first portion.

17. The method of claim 16, wherein the second portion overlaps the first semiconductor chip in a direction perpendicular to the first surface of the package substrate.

18. A semiconductor package comprising:
a package substrate;
a first semiconductor chip disposed on a first surface of the package substrate; and
a stiffener disposed on the first surface of the package substrate to be spaced apart from the first semiconductor chip and to surround the first semiconductor chip,
wherein an upper surface of the stiffener and an upper surface of the first semiconductor chip are disposed on an identical plane, and
the stiffener comprises a recess formed on the upper surface of the stiffener.

19. The semiconductor package of claim 18, further comprising an adhesive layer disposed between the stiffener and the first surface of the package substrate.

20. The semiconductor package of claim 18, wherein the first semiconductor chip comprises a logic chip.
